(19) United States
(12) Patent Application Publication
(10) Pub. No.: US 2020/0385866 A1
(43) Pub. Date: Dec. 10, 2020

(54) RF COMPONENTS WITH CHEMICALLY RESISTANT SURFACES

(71) Applicant: Applied Materials, Inc., Santa Clara, CA (US)

(72) Inventors: Swaminathan Srinivasan, Pleasanton, CA (US); Anantha K. Subramani, San Jose, CA (US); Karthik Janakiraman, San Jose, CA (US); Joseph F. Sommers, San Jose, CA (US)

(73) Assignee: Applied Materials, Inc., Santa Clara, CA (US)

(21) Appl. No.: 16/895,552

(22) Filed: Jun. 8, 2020

Related U.S. Application Data
(60) Provisional application No. 62/859,100, filed on Jun. 8, 2019.

(51) Int. Cl. C23C 16/505; C23C 16/44; C23C 16/02

(52) U.S. Cl. CPC C23C 16/505; C23C 16/0227; C23C 16/4405

(57) ABSTRACT

Described herein are RF components with a modified surface material to improve chemical resistance and decrease metal contamination within processing chambers. Also disclosed herein are methods of manufacturing and using the same. Some embodiments of the disclosure comprise a base material with a Young's modulus greater than or equal to 75 GPa. Some embodiments of the disclosure have a modified surface material comprising one or more of aluminum, lanathanum and magnesium.

### CROSS-REFERENCE TO RELATED APPLICATIONS

This application claims priority to U.S. Provisional Application No. 62/859,100, filed Jun. 8, 2019, the entire disclosure of which is hereby incorporated by reference herein.

### TECHNICAL FIELD

Embodiments of the present disclosure generally relate to coatings for RF components for deposition chambers. More specifically, some embodiments relate to the components, methods of making the components and methods of using the components.

### BACKGROUND

Methods for providing symmetric RF-active grounding may sometimes involve electrically-conductive gaskets, loops and/or other structural components. Traditionally RF plasma has been used in physical vapor deposition (PVD) chambers. As practitioners seek to expand the use of RF plasmas to chemical vapor deposition (CVD) chambers and beyond, concerns regarding metal contamination have arisen. Most materials from which RF components are formed are not resistant to the chamber cleaning chemistries (e.g., fluorine-containing radicals) used for CVD chambers.

Aluminum components would be expected to operate well in a CVD chamber cleaning environment that involves fluorine-containing radicals, particularly radicals generated from an RPS source acting on NF₃ gas. Yet, aluminum components do not have sufficient mechanical elasticity, especially at high temperature, for extended use in CVD chambers.

Therefore, there is a need in the art for novel materials or material coatings which combine high elasticity, chemical resistance and reasonable cost.

### SUMMARY

One or more embodiments of the disclosure are directed to an RF component comprising a base material having a Young's modulus greater than or equal to about 75 GPa with a modified surface material comprising one or more of aluminum, lanthanum or magnesium. The modified surface material is different from the base material. The RF component is selected from RF gaskets and RF loops.

Additional embodiments of the disclosure are directed to a method of chemical vapor deposition comprises depositing a material on a substrate within a deposition chamber comprising an RF component with a base material having a Young's modulus greater than or equal to about 75 GPa and a modified surface material comprising one or more of aluminum, lanthanum or magnesium. The modified surface material is different from the base material. The deposition chamber is cleaned with a cleaning reagent. The cleaning reagent does not produce metal contamination within the deposition chamber when exposed to the RF component.

Further embodiments of the disclosure are directed to a method of forming an RF component. The method comprises cleaning the exposed surface of a base material having a Young's modulus greater than or equal to about 75 GPa. A modified surface material is deposited on the base material. The modified surface material comprises one or more of aluminum, lanthanum or magnesium. The modified surface material is different from the base material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a cross-sectional view of a portion of an exemplary component before processing according to one or more embodiment of the disclosure;

FIG. 1B illustrates the portion of an exemplary substrate shown in FIG. 1A after the formation of a modified surface material on the base material according to one or more embodiment of the disclosure;

FIG. 2 shows an exemplary process flow for a method of chemical vapor deposition according to one or more embodiment of the disclosure; and

FIG. 3 shows an exemplary process flow for a method of forming an RF component according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise.

A “substrate” as used herein, refers to any substrate or material surface formed on a substrate upon which film processing is performed during a fabrication process. For example, a substrate surface on which processing can be performed include materials such as metals, metal alloys, and other conductive materials, depending on the application. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer may become the substrate surface for further processing steps.

Embodiments of the present disclosure relate to RF components (loops, gaskets) which possess sufficiently high elasticity while also being resistant to chamber chemistries. Some embodiments of this disclosure relate to the RF components. Some embodiments of this disclosure relate to methods for forming RF components which are resistant to chamber chemistries. Some embodiments relate to methods of deposition and cleaning within chamber comprising an RF component resistant to chamber chemistries.

Some embodiments of the disclosure provide RF components which can withstand chamber cleaning chemistries without producing metal contamination within the chamber. Some embodiments of the disclosure advantageously provide RF components comprising stainless steel or other highly elastic materials which can be utilized inside chamber environments with cleaning chemistries comprising fluorine containing radicals. Some embodiments of the disclosure advantageously provide for the generous use of stainless steel and other highly elastic materials in order to provide improved RF distribution functionality. Some embodiments of the disclosure advantageously reduce the complexity of purging and/or shielding mechanisms that would otherwise be required to provide a predetermined electrical functionality without producing metal contamination in the chamber.

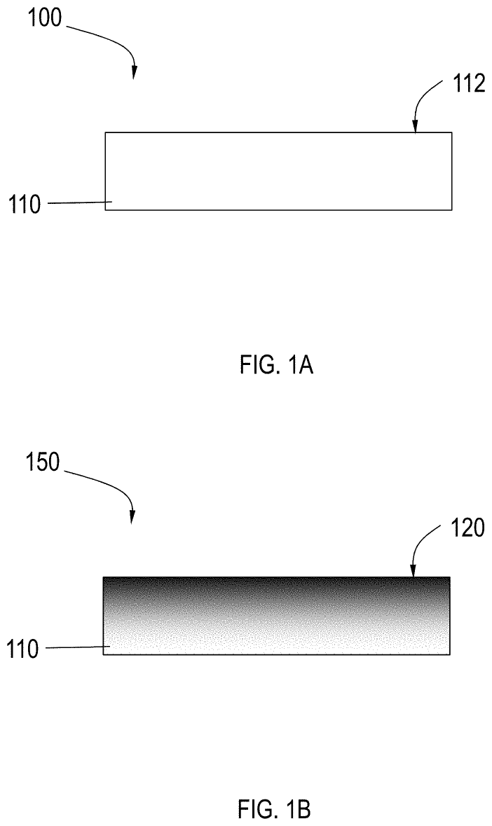

FIG. 1A illustrates a portion of an exemplary RF component before processing according to one or more embodiment of the disclosure. As used herein an RF component may refer to any component of an RF plasma system exposed within a processing chamber. In some embodiments, the RF component is selected from RF loops or RF gaskets. FIG. 1A shows a component 100 comprising a base material 110. The component may comprise additional materials, but the exposed surface 112 of at least a portion of the component 100 comprises the base material 110.

The base material 110 may be any suitable material with a sufficiently high elasticity. In some embodiments, the base material has a Young's modulus greater than or equal to about 75 GPa, greater than or equal to about 100 GPa, greater than or equal to about 150 GPa or greater than or equal to about 200 GPa. In some embodiments, the base material comprises stainless steel.

FIG. 1B illustrates the same portion of the component 100 shown in FIG. 1A after processing according to one or more embodiment of the disclosure to form component 150. As shown in FIG. 1B, the exposed surface of the base material has been treated so as to form a modified surface 120. The modified surface 120 is formed by the addition to the exposed surface 112 of a modified surface material.

In some embodiments, the modified surface material is diffuse within the base material. As stated above, the modified surface material modifies the surface of the base material. In some embodiments, the modified surface material is deposited as a continuous layer on base material. In some embodiments, the modified surface material is deposited as a discontinuous layer on the base material. Regardless of the continuity, the modified surface material produces a gradient of atomic composition where the concentration of the modified surface material is highest at the surface of the component (the modified surface 120) and slowly decreases away from the exposed surface of the base material. As shown in FIG. 1B, the gradation of concentration from black (high concentration of modified surface material) to gray to white (high concentration of base material) is expected to be gradual. While the gradation is expected to be gradual, the linear gradation shown in FIG. 1B is merely exemplary and not intended to be limiting.

The chemical protection afforded by the modified surface material does not require a continuous layer of the modified surface material on the base material. Accordingly, some embodiments of the disclosure advantageously provide a component which can withstand mechanical friction without losing chemical resistance. Stated differently, the loss of exterior layers from the modified surface material will not necessarily adversely affect the chemical resistance of the overall component as a sufficient amount of the modified surface material will have diffused within the base material of the component.

Some embodiments of the disclosure advantageously provide a diffuse modified surface material which provides at least partial coverage of the surface of the base material even if much of the pure modified surface material is eroded by friction. This diffusion makes the “coating” inherently robust and prolongs the useful life of the component against friction.

The modified surface material may be any suitable material which protects the base material 110 from chamber chemistries. The modified surface material is different from the base material. In some embodiments, the modified surface material comprises one or more of aluminum, lanthanum and magnesium.

In some embodiments, the modified surface material consists essentially of a single element. In some embodiments, the modified surface material consists essentially of aluminum. As used in this regard, a modified surface material which “consists essentially of a single element” modifies the base material by the addition of only one metallic element.

In some embodiments, the modified surface material comprises a metal alloy. In some embodiments, the modified material surface comprises a magnesium-aluminum alloy.

In some embodiments, the component 150 shown in FIG. 1B is resistant to corrosion by a cleaning reagent. In some embodiments, the cleaning reagent comprises fluorine radicals. In some embodiments, the fluorine radicals are generated remotely (RPS) or by microwave. In some embodiments, the fluorine radicals may be present in an NF₃ plasma. In some embodiments, the cleaning reagent comprises chlorine or oxygen atoms.

The modified surface material may be formed on the exposed surface 112 of the base material 110 by any suitable process. In some embodiments, the modified surface material is formed by one or more of electroplating, powder coating, physical vapor deposition, chemical vapor deposition (CVD), atomic layer deposition (ALD) or ion implantation. In some embodiments, the modified surface material is formed by diffusion-bonded CVD or ALD. In those embodiments utilizing diffusion-bonded CVD or ALD, the temperature of forfmation may be controlled to affect the level of diffusion of the modified surface material within the base material.

In some embodiments, the exposed surface of the base material may be cleaned before the formation of the modified surface material.

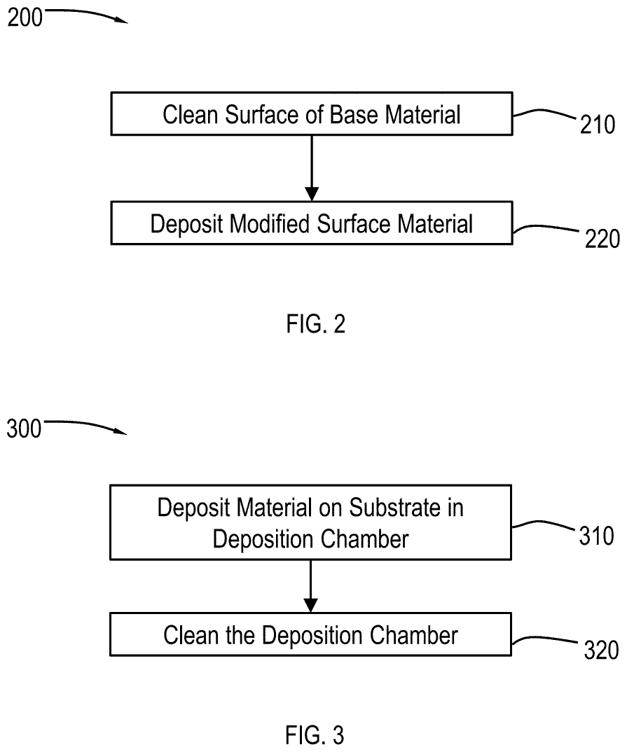

Some embodiments of the disclosure relate to methods of forming an RF component according to one or more embodiment of the disclosure. Referring to FIG. 2, an exemplary method 200 begins at 210 by cleaning the exposed surface of a base material. The base material is described above. In some embodiments, the base material has a Young's modulus greater than or equal to about 75 GPa.

The method 200 continues at 220 by depositing or forming a modified surface material on the base material. The modified surface material is described above. The modified surface material is different from the base material. In some embodiments, the modified surface material comprises one or more of aluminum, lanthanum or magnesium.

Some embodiments of the disclosure relate to a chemical vapor deposition chamber comprising an RF component according to one or more embodiment of this disclosure.

Some embodiments of the disclosure relate to methods of chemical vapor deposition. Referring to FIG. 3, an exemplary method 300 begins at 310 by depositing a material on a substrate within a deposition chamber. The deposition chamber comprises an RF component according to one or more embodiment described herein.

The method 300 continues at 320 by cleaning the deposition chamber with a cleaning reagent. The cleaning reagent has been described previously. In some embodiments, the RF component is resistant to corrosion by the cleaning reagent. In some embodiments, the cleaning reagent does not produce metal contamination within the deposition chamber when exposed to the RF component.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. An RF component comprising a base material having a Young's modulus greater than or equal to about 75 GPa with a modified surface material comprising one or more of aluminum, lanthanum or magnesium, the modified surface material different from the base material, the RF component selected from RF gaskets and RF loops.

2. The RF component of claim 1, wherein the base material comprises stainless steel.

3. The RF component of claim 1, wherein the base material has a Young's Modulus greater than or equal to about 150 GPa.

4. The RF component of claim 1, wherein the modified surface material consists essentially of a single element.

5. The RF component of claim 1, wherein the modified surface material comprises a metal alloy.

6. The RF component of claim 1, wherein the RF component is resistant to corrosion by a cleaning reagent.

7. The RF component of claim 6, wherein the cleaning reagent comprises fluorine radicals.

8. The RF component of claim 7, wherein the fluorine radicals are generated remotely or by microwave.

9. The RF component of claim 7, wherein the fluorine radicals are present in an NF₃ plasma.

10. The RF component of claim 1, wherein the modified surface material is diffuse.

11. The RF component of claim 1, wherein the modified surface material is formed by one or more of electroplating, powder coating, physical vapor deposition, chemical vapor deposition or ion implantation.

12. The RF component of claim 11, wherein the base material is cleaned before the modified surface material is formed.

13. A chemical vapor deposition chamber comprising one or more RF component of claim 1.

14. A method of chemical vapor deposition comprising:
depositing a material on a substrate within a deposition chamber comprising an RF component with a base material having a Young's modulus greater than or equal to about 75 GPa and a modified surface material comprising one or more of aluminum, lanthanum or magnesium, the modified surface material different from the base material; and
cleaning the deposition chamber with a cleaning reagent,
wherein the cleaning reagent does not produce metal contamination within the deposition chamber when exposed to the RF component.

15. The method of claim 14, wherein the base material comprises stainless steel.

16. The method of claim 14, wherein the cleaning reagent comprises fluorine radicals, chlorine or oxygen.

17. The method of claim 16, wherein the fluorine radicals are present in an NF₃ plasma.

18. A method of forming an RF component, the method comprising:
cleaning an exposed surface of a base material having a Young's modulus greater than or equal to about 75 GPa; and
depositing a modified surface material on the base material, the modified surface material comprising one or more of aluminum, lanthanum or magnesium, the modified surface material different from the base material.

19. The method of claim 18, wherein the modified surface material is deposited by one or more of electroplating, powder coating, physical vapor deposition, chemical vapor deposition or ion implantation.

20. The method of claim 18, wherein the modified surface material is deposited by diffusion-bonded CVD.
